(19) United States
(12) Patent Application Publication
(10) Pub. No.: US 2002/0064956 A1
(43) Pub. Date: May 30, 2002

(54) METHOD OF FORMING A STORAGE NODE OF A CAPACITOR

(76) Inventors: King-Lung Wu, Tainan Hsien (TW); Tzung-Han Lee, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/725,091

(22) Filed: Nov. 29, 2000

(51) Int. Cl. H01L 21/302

(52) U.S. Cl. 438/692

(57) ABSTRACT

A method of forming a storage node of a capacitor on a silicon substrate of a semiconductor wafer is achieved. A plurality of word lines and a first dielectric layer are positioned on the silicon substrate. A plurality of node contact holes are formed within the first dielectric layer. Both a polysilicon layer and a second dielectric layer are formed respectively on the surface of the semiconductor wafer. A planarization process is performed. The top surfaces of both the polysilicon layer and the second dielectric layer in the node contact hole are aligned with the surface of the first dielectric layer. A third dielectric layer, a plurality of bit lines and a fourth dielectric layer are formed respectively on the surface of the semiconductor wafer. Sections of the fourth, the third and the second dielectric layers are etched down to the surface of the polysilicon layer to form a capacitor trench. An amorphous silicon layer is formed on the surface of the capacitor trench to produce the final storage node.

### BACKGROUND OF THE INVENTION

1. Field of the Invention

The present invention relates to a method of forming a storage node of a capacitor, and more particularly, to a method of forming a storage node of a trench capacitor.

2. Description of the Prior Art

Dynamic random access memory (DRAM) is composed of numerous memory cells. A memory cell is composed of a metal oxide semiconductor (MOS) transistor and a capacitor. The MOS transistor is electrically connected to a word line while the capacitor is electrically connected to a bit line; together, they decide the address of a memory cell.

The capacitor of a memory cell is made up of two electrical layers on a semiconductor wafer. One electrical layer is used as a field plate while the other is used as a storage node. A cell dielectric layer is positioned between the two electrical layers as insulation. One of the electrical layers obtains induced charges while the other supplies a voltage, enabling the capacitor to memorize or output data. The storage node is electrically connected to a drain of the MOS transistor via a node contact to store or output data.

In order to increase both the integrity of and the simplification of fabrication, a landing pad and a self-alignment technology are widely used in the formation of a storage node of a capacitor, which electrically connects the MOS transistor to either the capacitor or the bit line. The semiconductor process is constantly improving and accordingly, the volume of the DRAM cell is also decreasing. Therefore, it is important to simultaneously improve the fabricating process and decrease the size of the DRAM cell.

Please refer to FIG. 1 to FIG. 3. FIG. 1 to FIG. 3 are schematic diagrams of a method of forming a storage node 30 according to the prior art. As shown in FIG. 1, a semiconductor wafer 10 comprises of a silicon substrate 12. A plurality of word lines 14 are positioned on the surface of the silicon substrate 12. A plurality of gates (not shown) are positioned in the word line 14 while a plurality of spacers 16 are positioned along either side. A doped area 18, positioned on the substrate 12 between the word lines 14, is used as a mutual drain for two gates in the word lines 14. Two doped areas 20, positioned on the substrate 12 outside the word lines 14, are used as sources for a gate in the word line 14.

According to the prior art, a dielectric layer 22 is first formed on the semiconductor wafer 10 to uniformly cover the word line 14. The dielectric layer 22, composed of silicon oxide, acts as an insulation layer. As shown in FIG. 2, a lithographic process is performed to form both a photoresist layer (not shown) on the surface of the dielectric layer 22, and a pattern of a landing pad 26 on the photoresist layer.

An anisotropic dry etching process is performed to form a contact plug hole 23 and a landing pad pit 25 that penetrate through the dielectric layer 22 to the surface of the doped area 18. A method of selecting different etching ratios to form both the contact plug hole 23 and the landing pit 25 is adopted through a combination of a stop layer or dry etching process, with a wet etching process. The photoresist layer is then completely removed. A thin film deposition process is performed to form a doped polysilicon layer (not shown) to completely fill in the contact plug hole 23 and the landing pad pit 25. An etching back process is performed to etch the doped polysilicon layer in order toalign it with the dielectric layer 22 to form a contact plug 24 and a landing pad 26.

As shown in FIG. 3, a silicon oxide layer 28 is deposited uniformly on the surface of the semiconductor wafer 10. A lithographic process is performed to form both a photoresist layer (not shown) on the silicon oxide layer 28, and a pattern of a node contact hole 29 on the photoresist layer. A dry etching process is performed to form a node contact hole 29 that penetrates through the silicon oxide layer 28 to the surface of the landing pad 26. The photoresist layer is removed and a doped polysilicon layer (not shown) is formed on the surface of the semiconductor wafer 10 to completely fill in the node contact hole 29. Another lithographic process is performed to form a photoresist layer (not shown) on the doped polysilicon layer and a pattern of a storage node 30 is defined on the photoresist layer. A dry etching process is performed to etch the doped polysilicon layer down to the surface of the silicon oxide layer 28 to simultaneously form a node contact 31 and a storage node 30 and to thereby finish the fabrication of the storage node 30.

Several lithographic processes are used to define patterns of the elements in the prior art method of forming a storage node, such as defining the active area, the landing pad pit and the contact plug hole, the node contact hole, and the storage node. A different mask is needed for each lithographic process resulting in an increase in production cost, an increase in the fabrication processes and a reduction in production yield. In addition, the line width of transistors decreases resulting in a lower etching tolerance; the effect increases the ability of other elements to be damaged and consequently, affects their yield during etching of the node contact hole.

### SUMMARY OF THE INVENTION

It is an objective of the present invention to provide a method of forming a storage node that leads to a reduction in production cost and an increase in yield. The method involves simultaneously increasing the area of the storage node and simplifying the fabrication of the storage node to achieve the above goals.

In a preferred embodiment, the present invention provides a method of forming a storage node of a capacitor on a semiconductor wafer. The semiconductor wafer comprises of a silicon substrate, a plurality of word lines positioned on the silicon substrate, and a first dielectric layer positioned on the semiconductor wafer to cover the word lines. A plurality of node contact holes are formed in the first dielectric layer. A polysilicon layer and a second dielectric layer are formed respectively on the surface of the semiconductor wafer. A planarization process is performed to align the surfaces of both the polysilicon layer and the second dielectric layer in the node contact hole with the surface of the first dielectric layer. A third dielectric layer, a plurality of bit lines and a fourth dielectric layer are formed respectively on the surface of the semiconductor wafer. Sections of the fourth, the third and the second dielectric layers are etched onto the surface of the polysilicon layer to form a capacitor trench. Lastly, an amorphous silicon layer is formed on the surface of the capacitor trench to finish the fabrication of the storage node.

It is an advantage of the present invention that the capacitor trench combines with the node contact hole to form the storage node. Then, an amorphous silicon layer is formed on the surface of the capacitor trench to function as the storage node. Thus, in contrast to the prior art, both the node contact and the landing pad are unnecessary in the formation of the storage node. Hence, the fabricating process of the storage node is greatly simplified.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 3 are schematic diagrams of the prior art method of forming a storage node.

FIG. 4 to FIG. 11 are schematic diagrams of a method of forming a storage node according to the present invention.

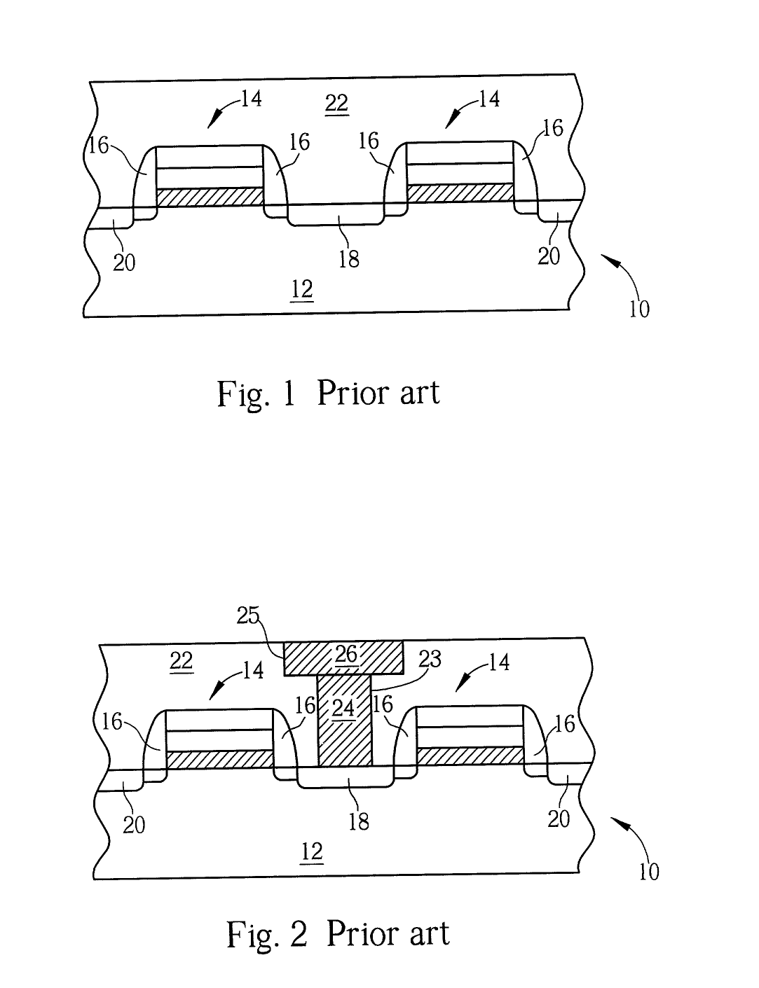

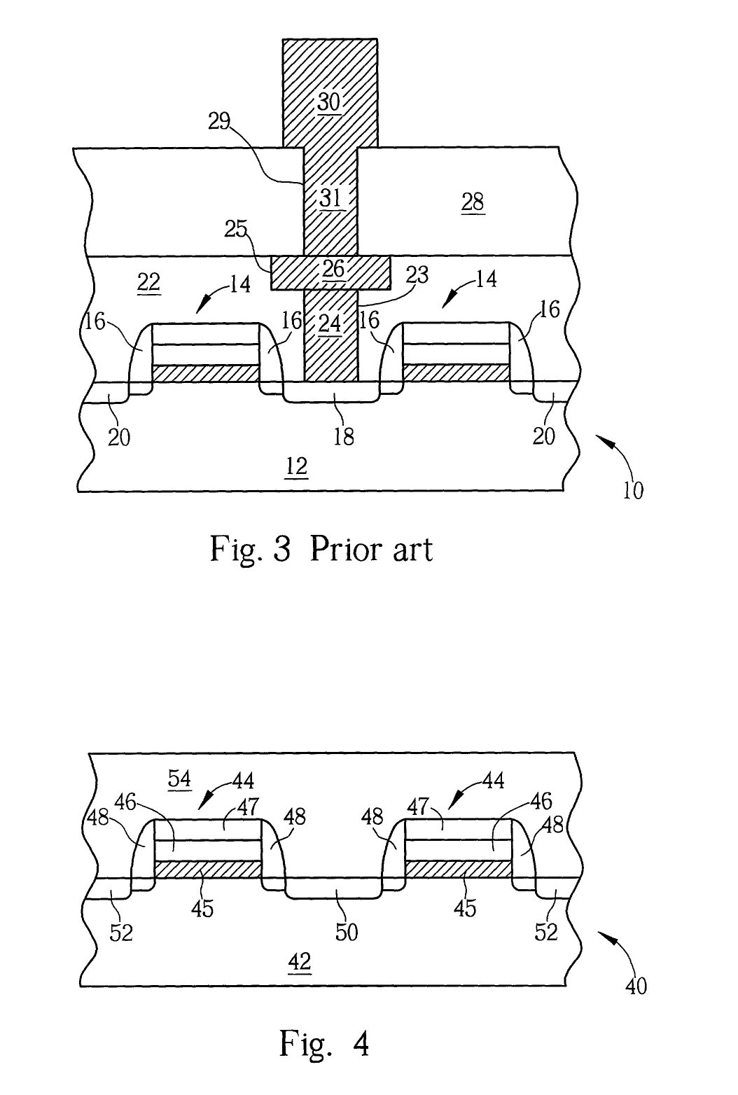

### DETAILED DESCRIPTION OF THE PREFERRED EMBODIMENT

Please refer to FIG. 4 to FIG. 11. FIG. 4 to FIG. 11 are schematic diagrams of a method of forming a storage node 75 according to the present invention. As shown in FIG. 4, a semiconductor wafer 40 comprises a silicon substrate 42. Two word lines 44 are positioned on the surface of the silicon substrate 42. A first dielectric layer 54 of silicon dioxide (SiO₂) is formed on the semiconductor wafer to cover the word lines 44. Each of the word lines 44 is composed of a gate (not shown) and a plurality of spacers 48 positioned on either side of the gate. A gate oxide layer (not shown), a doped polysilicon layer 45, a silicide layer 46 and a cap layer 47 are stacked respectively to form the gate. A doped area 50, positioned between the word lines 44 on the silicon substrate 42, is used as a mutual drain for the gates in the two word lines 44. Another doped area 52, formed on the silicon substrate 42 outside the two word lines 44, is used as a source for the gates.

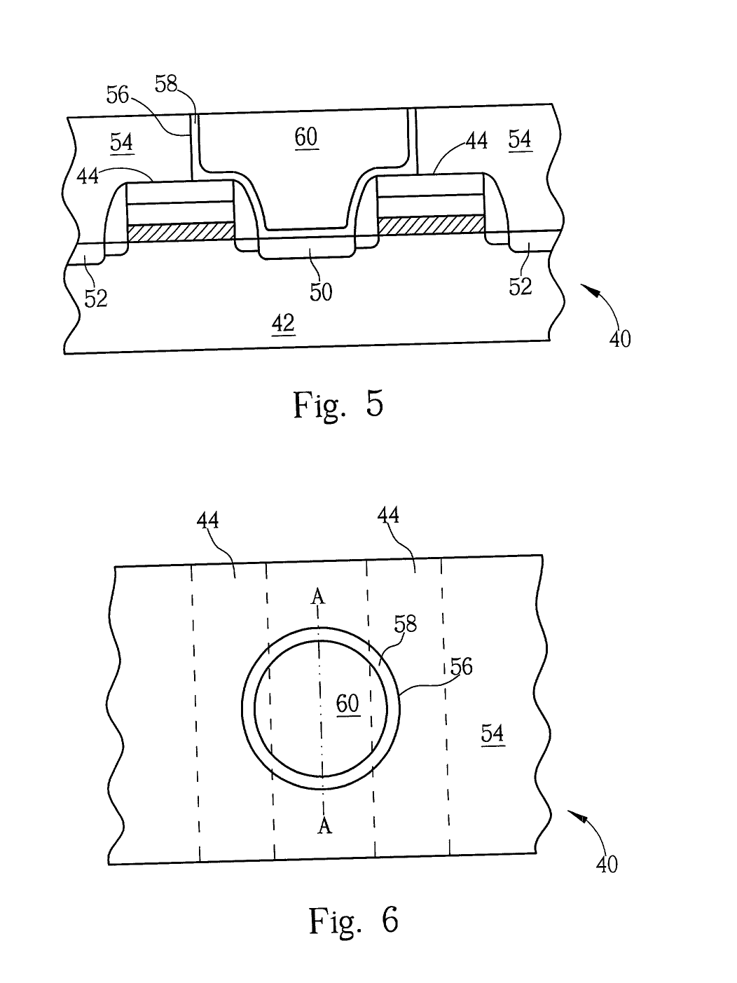

As shown in FIG. 5, a photoresist layer (not shown) is formed on the surface of the first dielectric layer 54. An etching process is performed on the surface of the first dielectric layer 54 uncovered by the photoresist layer to form a node contact hole 56. A polysilicon layer 58, with an approximate thickness of 500 angstroms (Å), is deposited on the surface of the semiconductor wafer 40. A plasma enhanced chemical vapor deposition (PECVD) process is then performed to deposit a second dielectric layer 60 of silicon dioxide on the surface of the polysilicon layer 58. The second dielectric layer 60, with a thickness of approximately 2000 angstroms, completely fills in the node contact hole 56. A planarization process, such as an etching back process or a chemical-mechanical polishing (CMP) process, is performed to remove both the second dielectric layer 60 and the polysilicon layer 58 from the first dielectric layer 54, using the first dielectric layer 54 as a stop layer. Consequently, the surfaces of the polysilicon layer 58 and the second dielectric layer 60 within the node contact hole 56 are aligned with the surface of the first dielectric layer 54.

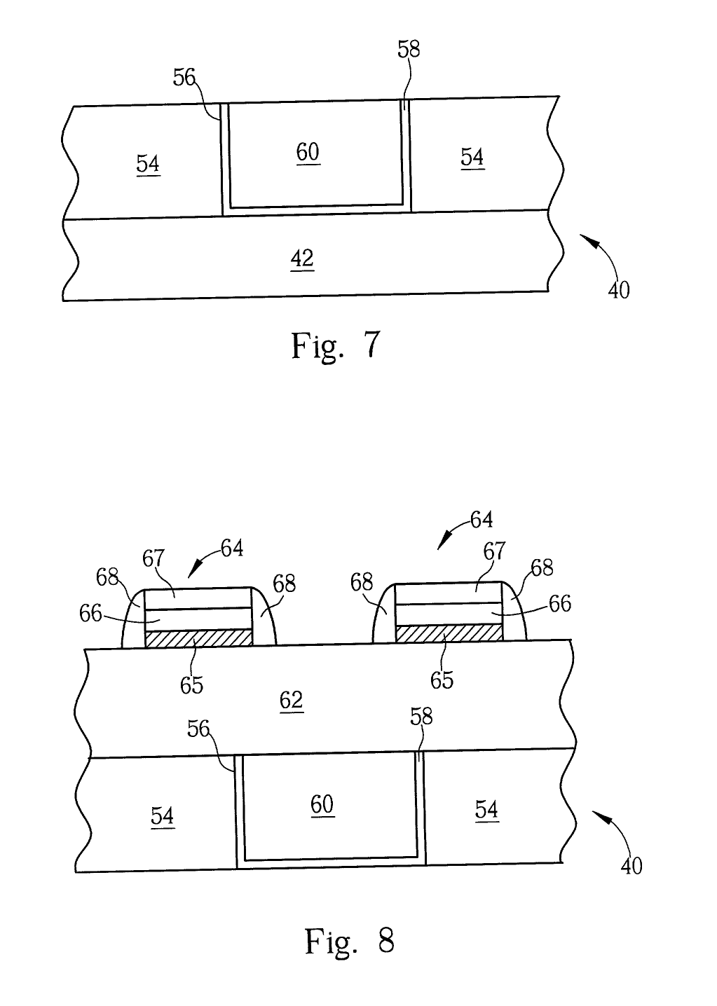

Please refer to FIG. 6. FIG. 6 is a top view of the structure shown in FIG. 5. As shown in FIG. 6, the node contact hole 56 of the semiconductor wafer 40 is positioned in the center of the two word lines 44. The second dielectric layer 60 and the polysilicon layer 58 surrounding the second dielectric layer 60 completely fill in the node contact hole 56. A sectional view along line AA in FIG. 6 is shown in FIG. 7. The structure of the semiconductor wafer 40 shown in FIG. 8 to FIG. 11 is represented atop the silicon substrate 42 of the structure shown in FIG. 7 and reveal subsequent processes being performed on the surfaces of the node contact hole 60 and the first dielectric layer 54 above the silicon substrate 42.

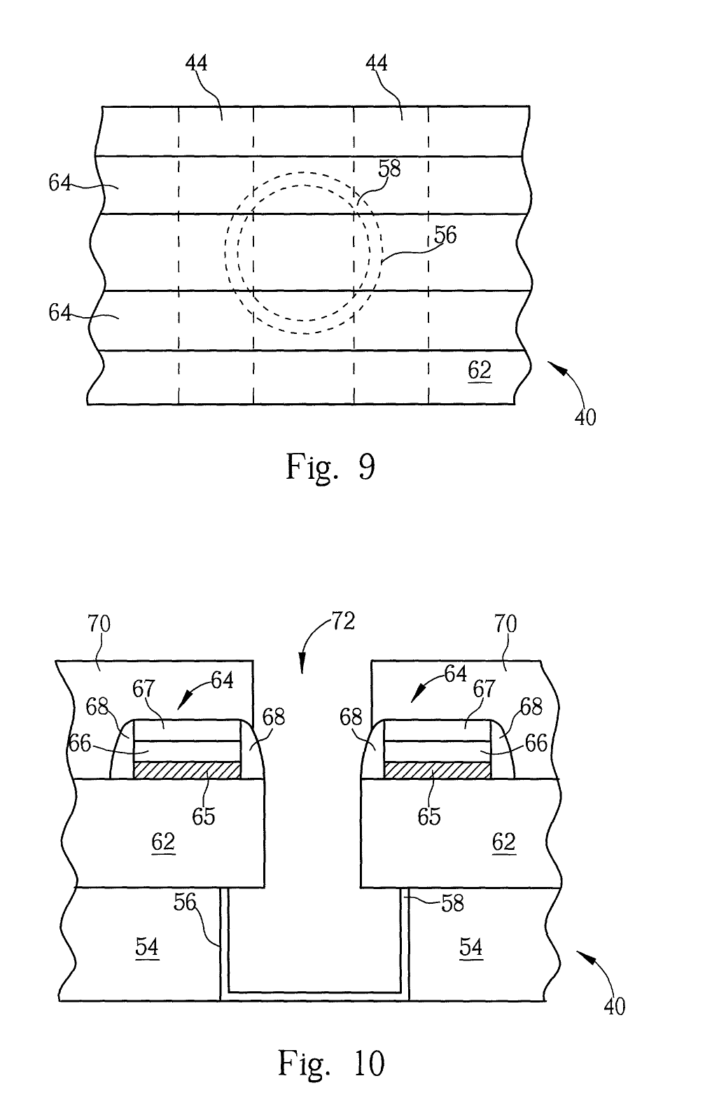

As shown in FIG. 8, a low-pressure chemical vapor deposition (LPCVD) process is performed and a tetra-ethyl-ortho-silicate (TEOS) layer with an approximate thickness of 2000 angstroms is formed on the surface of the semiconductor wafer 40. The TEOS layer is represented as the third dielectric layer 62. Two bit lines 64 are formed on the surface of the third dielectric layer 62, each of the bit lines 64 comprising a doped polysilicon layer 65, a silicide layer 66 and a cap layer 67 stacked respectively. A spacer 68 is formed on either side of the bit line 64. The relative position of the bit line 64 to the word line 44 is referred to in FIG. 9. FIG. 9 is a top view of the semiconductor wafer 40 shown in FIG. 8. As shown in FIG. 9, the word lines 44 and the bit lines 64 of the semiconductor wafer 40 are perpendicular to one another, and the node contact hole 56 is positioned across both the two word lines 44 and the two bit lines 64.

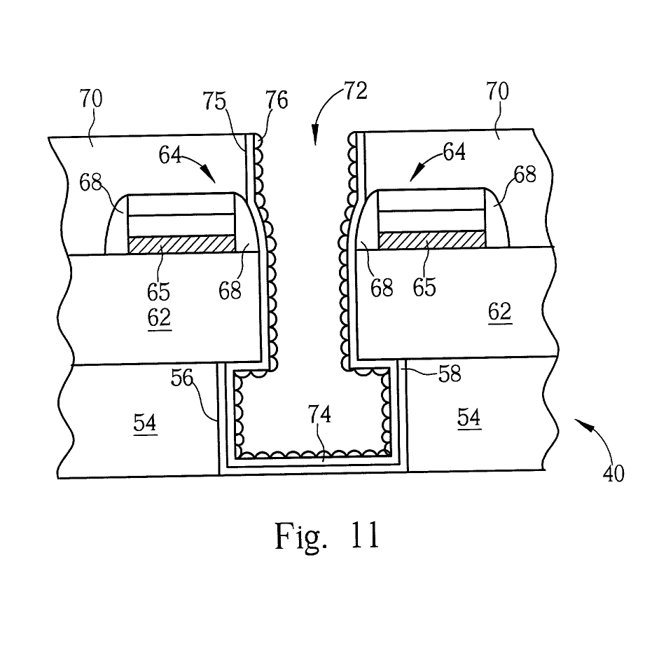

As shown in FIG. 10, a fourth dielectric layer 70, such as TEOS, is formed on the surface of the semiconductor wafer 40 and completely covers the bit lines 64. Then, a photoresist layer (not shown) is formed on the fourth dielectric layer 70. A lithographic process is performed to define a pattern of the storage node 75 on the photoresist layer. A dry etching process is performed using the photoresist layer as a hard mask and the polysilicon layer 58 as a stop layer. Sections of the fourth dielectric layer 70 and the third dielectric layer 62 and all of the second dielectric layer 60 are etched down to the surface of the polysilicon layer 58 to form a capacitor trench 72. The dry etching process may also be combined with a wet etching process to avoid destruction of the crystal structure of the polysilicon layer 58 during the dry etching process. For example, a dry etching process can be first used to etch sections of the fourth dielectric layer 70 and the third dielectric layer 62. Using the selection difference of the TEOS of layer 62 and the silicon dioxide of layer 60, a wet etching process can be next used to remove the second dielectric layer 60 above the polysilicon layer 58.

Lastly, as shown in FIG. 11, an amorphous silicon layer 74 of approximately 500 angstroms is formed on the surface of the semiconductor wafer 40. The amorphous silicon layer 74, a film thinner than the width of the capacitor trench 72, is deposited on the surface of the capacitor trench 72 to function as a conductive layer. A photoresist layer (not shown) is formed on the capacitor trench 72 to etch away the section of the amorphous silicon layer 74 covering the fourth dielectric layer 70. The storage node 75 is formed after the removal of the photoresist layer.

For the following fabrication of a capacitor, an oxide-nitride-oxide (ONO) process is required to form a capacitor dielectric layer on the surface of the amorphous silicon layer 74. As well, a conductive layer is needed to completely fill in the capacitor trench in order to cover the capacitor dielectric layer and function as a top electrode. These skills are known by those in the field of storage node fabrication and hence will not be described further. In addition, a hemi-spherical grain (HSG) process is used on the surface of the storage node 75, according to the present invention, to increase the total surface area of the storage node 75 and therefore reduce the refresh frequency of charges.

In contrast to the prior art, the present invention of a storage node utilizes a self-alignment contact (SAC) technology. The technology allows for both the etching of the node contact hole to form a capacitor trench and the direct deposition of an amorphous silicon layer on the surface of the capacitor trench to form the storage node. Hence, a node contact and a landing pad are not required in electrically connecting to the storage node. Thus, fabrication of the storage node is greatly simplified. Also, the problem of storage node collapse as a result of either neck-oxidation of the node contact or insufficient contact between the node contact and the storage node are prevented. In addition, the storage node of the present invention includes the surface of the fourth dielectric layer covering the bit lines to the surface of the first dielectric layer covering the word lines, constituting a very large total surface area for storing charges. Consequently, the refresh frequency of charges is greatly reduced to improve the performance of the storage node.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a storage node of a capacitor on a semiconductor wafer, the semiconductor wafer comprising a silicon substrate, a plurality of word lines positioned on the silicon substrate, and a first dielectric layer positioned on the surface of the semiconductor wafer to cover the word lines, the method comprising:
performing an etching process to form a plurality of node contact holes in the first dielectric layer;
forming a polysilicon layer and a second dielectric layer respectively on the surface of the semiconductor wafer, the second dielectric layer completely filling in the node contact holes;
performing a planarization process to remove both the second dielectric layer and the polysilicon layer from the surface of the first dielectric layer, and aligning the top surfaces of both the polysilicon layer and the second dielectric layer in the node contact hole with the surface of the first dielectric layer;
forming a third dielectric layer, a plurality of bit lines positioned on the third dielectric layer, a fourth dielectric layer positioned on the third dielectric layer to cover the bit lines, and a photoresist layer positioned atop the fourth dielectric layer;
performing a lithographic process to define a pattern of the storage node on the photoresist layer;
etching sections of the fourth, the third and the second dielectric layers down to the surface of the polysilicon layer to form a capacitor trench, utilizing the pattern of the photoresist layer as a mask and the polysilicon layer as a stop layer;
forming an amorphous silicon layer on the surface of the capacitor trench to finish fabrication of the storage node; and
performing a hemi-spherical grain (HSG) process to increase the total surface area of the storage node.

2. The method of claim 1 wherein each of the word lines comprises a gate oxide layer, a doped polysilicon layer, a first silicide layer, and a cap layer stacked respectively, and a first spacer positioned around either side of the word line.

3. The method of claim 1 wherein each of the bit lines comprises a doped polysilicon layer, a second silicide layer, and a cap layer stacked respectively, and a second spacer positioned around either side of the bit line.

4. The method of claim 1 wherein the planarization process is an etching back process.

5. A method of forming a storage node of a capacitor on a semiconductor wafer, the semiconductor wafer comprising a silicon substrate, a plurality of word lines positioned on the silicon substrate, and a first dielectric layer positioned on the surface of the semiconductor wafer to cover the word lines, the method comprising:
performing an etching process to form a plurality of node contact holes in the first dielectric layer;
forming a first conductive layer and a second dielectric layer respectively on the surface of the semiconductor wafer, the second dielectric layer completely filling in the node contact holes;
performing a planarization process to remove the second dielectric layer and the first conductive layer from the surface of the first dielectric layer to align the top surfaces of both the first conductive layer and the second dielectric layer in the node contact hole with the surface of the first dielectric layer;
forming a third dielectric layer, a plurality of bit lines positioned on the third dielectric layer, a fourth dielectric layer positioned on the third dielectric layer to cover the bit lines, and a photoresist layer positioned atop the fourth dielectric layer;
performing a lithographic process to define a pattern of the storage node on the photoresist layer;
etching sections of the fourth, the third and the second dielectric layers down to the surface of the first conductive layer to form a capacitor trench utilizing the pattern of the photoresist layer as a mask and the first conductive layer as a stop layer; and
forming a second conductive layer on the surface of the capacitor trench, the thickness of the second conductive layer being less than the smallest width of the capacitor trench.

6. The method of claim 5 wherein each of the word lines comprises a gate oxide layer, a doped polysilicon layer, a first silicide layer, and a cap layer stacked respectively, and a first spacer positioned around either side of the word line.

7. The method of claim 5 wherein each of the bit lines comprises a doped polysilicon layer, a second silicide layer, and a cap layer stacked respectively, and a second spacer positioned around either side of the bit line.

8. The method of claim 5 wherein the planarization process is an etching back process.

9. The method of claim 5 wherein both the first conductive layer and the second conductive layer are formed of polysilicon, amorphous silicon, silicide or metal.

10. The method of claim 9 wherein the second conductive layer is formed of an amorphous silicon, followed by the use of a hemi-spherical grain (HSG) process to increase the total surface area of the storage node.
